(19) United States
(12) Patent Application Publication
(10) Pub. No.: US 2026/0309315 A1
(43) Pub. Date: Oct. 8, 2026

(54) Foldable Luminaires

(71) Applicant: SIGNIFY HOLDING B.V., EINDHOVEN (NL)

(72) Inventors: RIFAT ATA MUSTAFA HIKMET, EINDHOVEN (NL); TIES VAN BOMMEL, HORST (NL)

(21) Appl. No.: 19/100,787

(22) PCT Filed: Jul. 24, 2023
(86) PCT No.: PCT/EP2023/070411

§ 371 Date: Feb. 3, 2025

(30) Foreign Application Priority Data
Aug. 2, 2022 (EP) 22188282.2

(51) Int. Cl. F21V 21/14; F21S 2/00; F21V 5/00; F21V 7/00; F21Y 103/10; F21Y 115/10

(52) U.S. Cl. CPC F21V 21/14; F21S 2/005; F21V 5/00; F21V 7/00; F21Y 2103/10; F21Y 2115/10

(57) ABSTRACT

A foldable luminaire (100) is provided. The foldable luminaire comprises a body (110) having a thickness (d) and comprising a top side (110a) and a bottom side (110b) separated by the thickness. The foldable luminaire also comprises a plurality of LED light sources (120,155) arranged to, in operation, emit LED light (125). The foldable luminaire further comprises a first flexible material later (130) attached at the bottom side of the body. The first flexible material layer comprises electrical connecting elements for providing power to the LED light sources. The foldable luminaire further comprises a plurality of light shaping elements (460) arranged in the body configured to at least partially shape or redirect the light into luminaire light (105). A plurality of slits (140) is formed in the body extending from the top side to the bottom side such that a plurality of body segments (1, 2, . . . , n) with respective length (L1, L2, . . . , Ln) are formed in the body. The plurality of slits corresponds to at least one rotational axis (R1, R2, . . . , Rn) extending in the first flexible material layer. Each of the plurality of body segments comprises a LED light source of the plurality of LED light sources and a light shaping element of the plurality of light shaping elements. A rotational axis of the at least one rotational axis extends along a direction (D) corresponding to the direction of its associated slit. At least one of the plurality of body segments is rotatable about the at least one rotational axis for folding of the foldable luminaire.

### TECHNICAL FIELD

The present invention relates to lighting arrangements or luminaires. More specifically, the present invention relates to foldable luminaires configured to provide an aesthetically desirable illumination and/or a convenient way of folding and installing the luminaires.

### BACKGROUND

The use of luminaires, such as troffers, continues to be widespread around the world. In general troffers using light emitting diodes (LED) for illumination purposes continues to attract attention. Another term for troffers with integral LEDs is LED light panels. Troffers are often long and large light fixtures with rectangular shapes. Troffers are used in many environments, for example in office spaces, schools and lab facilities.

In general, troffers are installed in the ceiling to provide lighting to a room. Due to their large size, the light fixtures may however be hard to install. Further, the troffers are hard to transport.

Hence, it is an object of the present invention to improve the luminaires and troffers used today, for example for facilitating installation and/or transport.

US 2017/254518 discloses a flexible illumination panel having a layered sheet-form configuration and including a bottom flexible sheet of a rigid material, a top flexible sheet formed by an optically transmissive, elastic material, and a two-dimensional array of light emitting diodes (LEDs) mounted to the bottom flexible sheet and encapsulated between the top and bottom flexible sheets. The LEDs may further include rigid substrates (submounts) attached to the bottom flexible sheet.

### SUMMARY

It is of interest to provide a troffer that can be more easily installed and transported. Further, it is of interest to provide a troffer or luminaire that can be adjusted in order to provide more aesthetically pleasing lighting.

This and other objects are achieved by providing a foldable luminaire having the features defined in the independent claims. Preferred embodiments are defined in the dependent claims.

Hence, according to some embodiments of the present disclosure, there is provided a foldable luminaire comprising a body having a thickness and comprising a top side and a bottom side separated by the thickness. The foldable luminaire further comprises a plurality of LED light sources arranged to, in operation, emit LED light. The foldable luminaire further comprises a first flexible material layer attached at the bottom side of the body. The first flexible material layer comprises electrical connecting elements for providing power to the LED light sources. The foldable luminaire further comprises a plurality of light shaping elements arranged in the body configured to at least partially shape or redirect the LED light into luminaire light. A plurality of slits is arranged in the body. The plurality of slits extending from the top side of the light shaping body to the bottom side of the light shaping body such that a plurality of body segments with respective lengths are formed in the body. A slit thereby corresponds to (or is associated with) at least one rotational axis extending in the first flexible material layer between. Each of the plurality of body segments comprises a LED light source of the plurality of LED light sources and a light shaping element of the plurality of light shaping elements. A rotational axis of the at least one rotational axis extends along a direction corresponding to the direction of its corresponding (or associated) slit. At least one of the plurality of light shaping segments is rotatable about the at least one rotational axis for folding of the foldable luminaire.

By “foldable” is meant that the luminaire may be folded. As described, the plurality of body segments are rotatable about the rotational axes for folding the luminaire. However, it is understood that foldable also includes folding less than 180 degrees, as depicted and discussed in the present disclosure. For example, folding may also include simply bending or flexing the luminaire for changing the shape of luminaire.

By “LED light source” is meant a light emitting diode light source. A light emitting diode light source may in general comprise one or more light emitting diodes. Light emitting diodes (LEDs) may for example include laser diodes.

By “flexible material layer” is here meant a material that provides flexibility and can be folded. The flexible material layer may be made from any suitable material and may be attached to the body in any conventional way, for example by glue or adhesives. It can also be integral part of the body and the body is cut to a certain level so that it can be folded. For example, a channel plate where a cut is made from top layer to just above the bottom layer. Since the flexible material layer is flexible, the segments formed in the light shaping body can be folded at the rotational axes formed by the plurality of slits.

By “slit” is herein meant for example a cut, split or opening between two body segments. For example, the body may be cut for creating the body segments with slits in-between or the body segments may be placed or ordered adjacent to each other with slits in-between, in other words an assembly of body segments.

The thickness of the luminaire body may vary depending on a number of factors. For example, in case the material of the body is stiff or rigid, the thickness may in general be smaller. In some cases, if the material of the body is more flexible or soft, the thickness may be larger. However, the thickness does not need to be related to the stiffness of the body. Further, depending on the size of the foldable luminaire, the thickness may also change. In case the area of the foldable luminaire is larger, the thickness may be larger and vice versa. In general, the thickness may be at least 1 cm, more preferably at least 2.5 cm and most preferably at least 3 cm. In the same way, the thickness may be equal or less than 10 cm, preferably equal or less than 8 cm, more preferably equal or less than 6 cm, most preferably equal or less than 5 cm. It is understood that these values may vary depending on the type of foldable luminaire and its application.

Luminaires, for example troffers, are today often made in one piece which makes them harder to transport or to install into luminaire holders. By forming a plurality of slits (or cuts) in the body, the present embodiments provide a luminaire with body segments that can be folded in a convenient way for either transport or for fitting into luminaire holders. The present embodiments provide also that the body can be at least partially folded or shaped in order to achieve certain aesthetic effects. In other words, the luminaire according to the present embodiments can be folded for facilitating transport and/or installation (easier fitting) into a holder or at least partially folded, shaped or formed for providing light shaping effects that otherwise would be difficult to achieve with a luminaire made from a body.

According to an embodiment, the body extends along a first axis. The plurality of slits intersects the first axis so that the body segments are formed extending along the first axis. The first flexible material layer extends, along the first axis, from a first body segment to a last body segment. In some implementations, the plurality of slits may be orthogonal to the first axis. In the present embodiments, the succession of body segments along the first axis corresponds to the extension of the body along the first axis. The luminaire may for example have a rectangular, or oblong shape. The flexible material layer extends from the first to the last body segment and a rotational axis is formed between two successive body segments. The body segments can be folded about the rotational axes.

In the present disclosure, a body segment (or element or block) may be referred to as the first, second, third, fourth, and so forth in relation to its position along the axis of extension of the body. For example, the luminaire may be seen as extending from left to right along the axis, wherein the body segment being at the left end is the first body segment and the body segment positioned at the right end (i.e., the opposite end) is the body segment.

According to an embodiment, the flexible material layer is formed by two layers, one for flexible folding and the other for providing electrical connection to the LEDs.

According to an embodiment, the light shaping element is chosen from at least one of a specular reflecting collimator, a diffuse reflective collimator, a total internal reflection collimator, and a collimator lens. In order to provide an aesthetically pleasant light or in order to focus or guide the LED light, the body may include reflectors or reflective cups. The body may also include other types of light forming or light reflecting materials, such as lenses or other means for shaping light.

According to an embodiment, the first body segment has a first length along the first axis and a third body segment has a third length along the first axis different from the first length.

According to an embodiment, a fourth body segment has a fourth length along the first axis different from the first length and the third length.

According to an embodiment, a first body segment has a first length along the first axis and a second body segment, arranged adjacent to the first body segment along the first axis, has a second length along the first axis equal to the first length. By adjacent is here meant directly after or next to along the axis. It will be appreciated that, in the present disclosure, “adjacent to” does not necessarily mean that the first and second body segments are touching each other as a slit is formed between them, thereby providing a small gap or distance physically separating the body segments. In the present embodiment, the second body segment can be folded over the first body segment. As they are equal in length, the foldable luminaire can be folded into a smaller configuration, for example for transport. The second body segment may be folded over a rotational axis formed in the first flexible material layer between the first and second body segments. The second body segment may be rotated by 180 degrees in order to be placed on the first body segment.

According to an embodiment, a third body segment, arranged adjacent to the second body segment along the first axis, has a third length along the first axis. The third length is less than the first length and the second length. In some implementations, the third length may be equal to the thickness of the body. The third body segment may be folded by a 90 degrees rotation so that, in a folded configuration or state of the luminaire, it extends orthogonally compared to the direction of extension of the first and second body segments.

According to an embodiment, the respective length along the first axis of at least one of every other body segment, starting from a third body segment arranged directly after the second body segment along the first axis is equal to the thickness multiplied by an integer Z, wherein Z starts at one and increases by one for every other body segment. In the present embodiment, a third body segment has a length along the first axis equal to the thickness, a fifth body segment has a length along the first axis equal to two times the thickness, a seventh body segment has a length along the first axis equal to three times the thickness, etc. The present embodiment provides body segments that are conveniently foldable over each other in order to provide a compact and neatly folded foldable luminaire.

According to an embodiment, the respective length along the first axis of at least one of every other body segment, starting from a fourth body segment arranged directly after the third body segment along the first axis, is equal to the first length plus the thickness multiplied by an integer Y, wherein Y starts at zero and increases by one for every other body segment. In other words, a fourth body segment has a length along the first axis equal to the first length, a sixth body segment has a length along the first axis equal to the first length plus the thickness, an eighth body segment has a length along the first axis equal to the first length plus two times the thickness, etc. These dimensions facilitate the folding of the luminaire.

According to an embodiment, the body extends in a square or rectangular shape along a first axis and a second axis. Such shapes are suitable for use in in locations like schools, office environments, and hospitals where standard troffers or luminaires usually are square or rectangularly shaped.

According to an embodiment, the foldable luminaire further comprises a second flexible material layer attached at the top side of the body. The second flexible material layer may be similar to the first flexible material layer and be made from the same basic material. It may also be made from another, different material. The second flexible material layer may be attached to the body by any conventional means, for example by adhesive or glue. By providing a second flexible material layer on the top side of the body, the foldable luminaire may be folded in more than one direction.

According to an embodiment, the plurality of slits includes two slits formed in the body. A first slit of the two slits is formed along a first middle line of the square or rectangular shape along the first axis and a second slit of the two slits extends along a second middle line of the square or rectangular shape along the second axis and orthogonal to the first middle line. In the present embodiment, the body is divided into four body segments by providing two slits along the middle lines of the body.

According to an embodiment, the first flexible material layer attached at the bottom side of the body at least partially covers the first slit of the two slits. The second flexible material layer attached at the top side of the body at least partially covers the second slit of the two slits. The present embodiment is advantageous since the foldable luminaire may be easily folded over itself into a compact formation. The foldable luminaire may be folded along a rotational axis formed by the first of the two slits. The foldable luminaire can then be folded again along a rotational axis formed by the second slit.

According to an embodiment, the foldable luminaire further comprises a LED strip comprising the plurality of LED light sources and optionally the first flexible material layer. The LED light sources may be attached to a flexible material layer and thusly form a LED strip. Alternatively, the LED light sources (itself) may be a LED strip and it may be disposed on the first flexible material. The LED strip may be any conventional or available LED strip. The LED strip may then be part of the body forming the foldable luminaire.

According to an embodiment, the LED strip comprises a plurality of light emitting diodes configured to emit LED light. The light emitting diodes may be distributed along the LED strip, and the light emitting diodes may be arranged in at least one of the plurality of body segments.

According to an embodiment, a respective number, depending on the respective length of the body segment, of light emitting diodes are arranged in each light shaping segment. As an example, in case a body segment is longer than another body segment, it may have a higher number of light emitting diodes.

According to an embodiment, at least one of the body segments is made from a rigid material. In case the foldable luminaire is formed from a rigid material it may be even harder to fit into a holder due to its inflexibility. Therefore, for embodiments where one, some or all of the body segments are rigid, the provision of a flexible layer and the slits in the body improve the foldability of the luminaire.

In embodiments, the foldable luminaire, and especially the plurality of body segments, may be configured such that the foldable luminaire has a folded state according to a log cabin pattern/principle.

Further objectives of, features of, and advantages with, the embodiments of the present disclosure will become apparent when studying the following detailed disclosure, the drawings and the appended claims. Those skilled in the art will realize that different features of the present invention can be combined to create embodiments other than those described in the following.

### BRIEF DESCRIPTION OF THE DRAWINGS

This and other aspects of the present invention will now be described in more detail, with reference to the appended drawings showing embodiment(s) of the invention.

FIGS. 1a, 1b and 1c schematically show a foldable luminaire according to an exemplifying embodiment of the present disclosure.

FIGS. 2a and 2b schematically show a foldable luminaire according to an exemplifying embodiment of the present disclosure.

FIGS. 3a, 3b and 3c schematically show a foldable luminaire according to an exemplifying embodiment of the present disclosure.

FIGS. 4a, 4b and 4c schematically show a foldable luminaire according to an exemplifying embodiment of the present disclosure.

### DETAILED DESCRIPTION

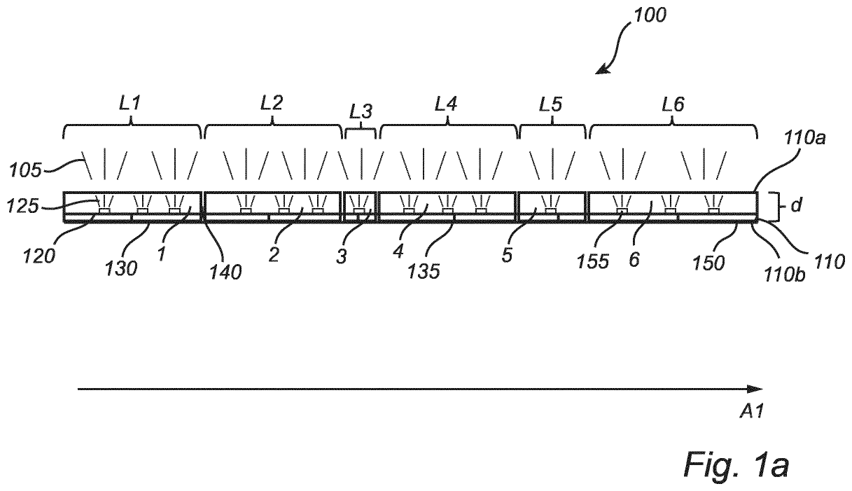

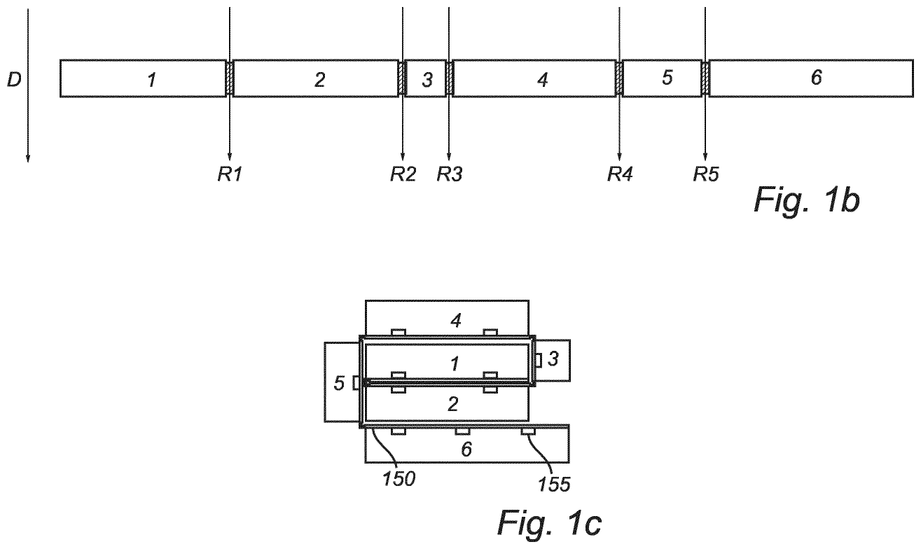

FIG. 1a schematically shows a foldable luminaire 100 according to an exemplifying embodiment of the present disclosure.

The foldable luminaire 100 comprises a body 110. The body has a thickness d and a top side 110a and a bottom side 110b separated by the thickness d. The foldable luminaire 100 further comprises a plurality of light emitting diode (LED) light sources 120, 155 arranged to emit LED light 125. The LED light 125 may for example be directed towards or out of the body 110. The foldable luminaire 100 further comprises a plurality of light shaping elements arranged in the body 110 and configured to at least partially shape or redirect the LED light 125 into luminaire light 105. The body 110 may for example include reflectors or reflective cups in order to shape or direct the LED light 125 into luminaire light 105. The luminaire body 105 may also include lenses or other light bending materials.

The foldable luminaire 100 further comprises a first flexible layer 130 attached at the bottom side 110b of the body 110. The flexible material layer 130 may also be attached to the top side 110a of the body 110. The first flexible material layer 130 comprises electrical connecting elements 135 for providing power to the LED light sources 120,155. The flexible material layer 130 may be made from any suitable flexible material, such as plastic or rubber or paper composite. Further, it can be an integral part of the body 110 such as a channel plate. The channel plate may also be a multi-channel plate also referred to as a multi-wall sheet. The flexible material layer 130 may be attached to the bottom side 110b of the body 110 using any attaching technique, for example tape, glue or other adhesives.

In the body 110, a plurality of slits (for example cuts through the body 110) 140 are formed. The plurality of slits 140 are extending from the top side 110a of the body 110 to the bottom side 110b of the body 110 such that a plurality of body segments 1, 2, 3, 4, 5, 6 with respective lengths L1, L2, L3, L4, L5, L6 are formed in the body 110. The slits can also extend from the bottom side 110b to the top side 110a. In the present embodiment, as shown in FIG. 1a, six body segments 1, 2, 3, 4, 5, 6 are formed in the body 110. It is however an example and an arbitrary number, n, of body segments may be formed by a plurality of slits 140. The plurality of slits 140 thereby corresponds to a plurality of rotational axes (as depicted in FIG. 1b) extending in the first flexible material layer 130 between the plurality of body segments 1, 2, 3, 4, 5, 6. One rotational axis is associated with one of the plurality of slits 140 and extends along a direction (D in FIG. 1b) corresponding to the direction of its associated slit. The plurality of body segments 1, 2, 3, 4, 5, 6 are rotatable about the plurality of rotational axes for folding of the foldable luminaire. The rotational axes are formed in the first flexible layer 130, at positions corresponding to the slits 140 (i.e., between two consecutive body segments) such that the first flexible layer 130 still hold the body 110 together. In some implementations, only one rotational axis may be formed, while in other implementations, such as shown in FIG. 1a, a plurality of rotational axes is formed. Each of the plurality of body segments comprises a LED light source of the plurality LED light sources and a light shaping element of the plurality of light shaping elements. The body segments may also themselves be light shaping elements. In other words, the body segments may be made from material such that they shape light and act as light shaping elements.

In other words, in the body 110, a plurality of slits 140 are formed. The slits 140 extend from the top side 110a to the bottom side 110b (or the other way around) so that body segments 1, 2, 3, 4, 5, 6 are formed. The body segments 1, 2, 3, 4, 5, 6 are held together by the flexible material layer 130. As the slits 140 separate the body segments 1, 2, 3, 4, 5, 6, they can be rotated or folded over each other, or at least bended towards each other (without necessarily lying against each other), and about the rotational axes. At each slit, a rotational axis is formed in the first flexible layer, and each body segment can be rotated or folded about at least one rotational axis.

In FIG. 1a, the body 110 extends along a first axis A1, and the plurality of slits intersects the first axis A1 so that the body segments 1, 2, 3, 4, 5, 6 are formed extending along the first axis A1. The first flexible material layer 130 extends, along the first axis A1, from the first body segment 1 to the last body segment 6.

In FIG. 1a, the body segments 1, 2, 3, 4, 5, 6 have respective lengths L1, L2, L3, LA, L5, L6. The first body segment 1 has a length L1 along the first axis A1 and the third body segment 3 has a length L3 along the first axis A1 different from the first length L1. As shown in FIGS. 1a-1c, the fourth body segment 4 has a fourth length L4 along the first axis A1 different from the third length L3 but the same as the first length L1. The fourth length L4 may however be different from the first length L1 and the third length L3.

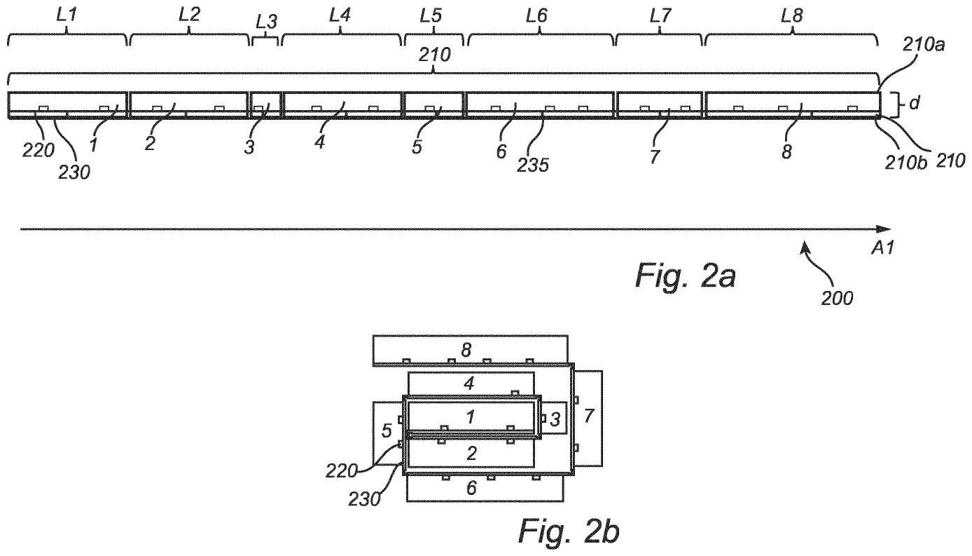

The first body segment 1 has a first length along the first axis A1 and the second body segment 2, arranged adjacent to the first body segment 1 along the first axis A1, has a second length L2, along the first axis A1, that is equal to the first length L1. This provides that, when the body shaping segment 1 is folded over the second body segment 2, the two segments will match. In FIG. 1a, the respective length along the first axis A1 of every other body segment 3, 5, starting from the third body segment 3 arranged directly after the second body segment along the first axis A1, is equal to the thickness d multiplied by an integer Z, wherein Z starts at one and increases by one for every other body segment 3, 5. This provides that, as shown in FIG. 1a, the third body segment 3 has a length L3 equal to the thickness d and the fifth body segment 5 has a length L5 equal to the thickness d times two. In case the foldable luminaire 100 would have a seventh body segment (as in FIG. 2a) it would have a length equal to three times the thickness d.

Further, as shown in FIG. 1a, the respective lengths along the first axis A1 of every other body segment 4, 6, starting from a fourth body segment 4 arranged directly after the third body segment 3 along the first axis A1, is equal to the first length L1 plus the thickness d multiplied by an integer Y, wherein Y starts at zero and increases by one for every other body segment 4,6. This provides that, as shown in FIG. 1a, the fourth body segment 4 has a length L4 equal to the first length L1 and the sixth body segment 6 has a length L6 equal to the first length L1 plus the thickness d. In case the foldable luminaire 100 had an eighth body segment (as in FIG. 2a), it would have a length equal to the first length plus two times the thickness d.

With the above-mentioned exemplary lengths L1, L2, L3, L4, L5, L6, the body segments 1, 2, 3, 4, 5, 6 can be folded into the formation shown in FIG. 1c.

The LED light sources 120,155 and the flexible material layer 130 may together form a LED strip 150 or the LED light sources 120,155 itself may be a LED strip. The LED strip may comprise a plurality of light emitting diodes (LEDs) 155 configured to emit the LED light 125. The LEDs 155 are distributed along the LED strip 150 and the LEDs are arranged in the plurality of body segments 1, 2, 3, 4, 5, 6. In FIG. 1, the LEDs are distributed among all of the body segments 1, 2, 3, 4, 5, 6. The LEDs 155 may be distributed so that a number of LEDs 155 in a body segment depends on the respective length of the body segment. For example, the longer the body segment the more LEDs 155 may be arranged in, or in the vicinity of, it.

The body 110 may be made from any typical or conventional material. The body segments 1, 2, 3, 4, 5, 6, may also be made from any material. They may for example be made from a rigid material.

The thickness d of the luminaire body 110 may vary depending on whether the material of the body 110 is more stiff (rigid) or more flexible (soft), or on the size of the foldable luminaire 100. For example, the thickness d may be at least 1 cm, more preferably at least 2.5 cm and most preferable at least 3 cm. In the same way, the thickness d may be equal or less than 10 cm, preferably equal or less than 8 cm, more preferably equal or less than 6 cm, most preferably equal or less than 5 cm.

The size of the foldable luminaire 100 may vary and may for example be a standard size for a luminaire or troffer for use in locations such as schools, office spaces and hospitals. The foldable luminaire 100 depicted in FIG. 1 may for example have a length of one meter or approximately one meter.

The plurality of slits 140 may separate the body segments 1, 2, 3, 4, 5, 6 by any suitable distance. However, the width of the plurality of slits 140 is preferably held small for stability of the foldable luminaire 100. The slits 140 may for example have a width of 0.1 to 3 mm, preferably 0.2 to 2 mm, more preferable 0.25 to 1.5 mm and most preferably 0.3 to 1 mm.

The flexible material layer 130 may be formed by two layers, one for flexible folding and one for providing electrical connection to the LEDS.

FIG. 1b schematically shows a foldable luminaire 100 according to an exemplifying embodiment of the present disclosure.

FIG. 1b and FIG. 1a show the same foldable luminaire 100 but from different perspectives. In FIG. 1b, the foldable luminaire 100 is seen from the top side 110a. In FIG. 1b, the rotational axes R1, R2, R3, R4, R5 corresponding to the plurality of slits are shown. The rotational axes R1, R2, R3, R4, R5 extend along a direction D corresponding to the direction of the slits 140.

FIG. 1c schematically shows a foldable luminaire 100 according to an exemplifying embodiment of the present disclosure.

FIG. 1c shows the foldable luminaire described with reference to FIGS. 1a and 1b but in a folded configuration or folded state. The specific lengths L1, L2, L3, L4, L5, L6 of the body segments 1, 2, 3, 4, 5, 6 in the embodiment of the foldable luminaire 100 of FIGS. 1a, b, c provide that the foldable luminaire 100 can be folded compactly, as illustrated in FIG. 1c.

FIGS. 2a and 2b show a foldable luminaire 200 according to another exemplifying embodiment of the present disclosure.

FIG. 2a shows the foldable luminaire 200 in an unfolded state while FIG. 2b shows the foldable luminaire 200 in a folded state. The foldable luminaire 200 is similar to the foldable luminaire described above with reference to FIGS. 1a, 1b, 1c and may comprise any of the features of the foldable luminaire 100. The foldable luminaire 200 differs in that it includes eight body segments 1, 2, 3, 4, 5, 6, 7, 8. The lengths of the body segments 1, 2, 3, 4, 5, 6, 7, 8 provide for a compact folding of the foldable luminaire 200, as can be seen in FIG. 2b.

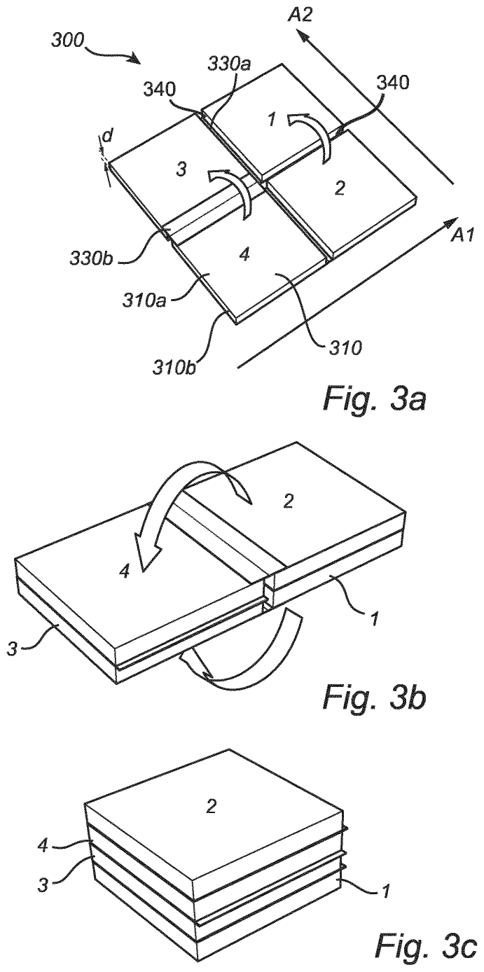

FIG. 3a shows a foldable luminaire 300 according to yet another exemplifying embodiment of the present disclosure.

The foldable luminaire 300 comprises a body 310 having a thickness d and a top side 310a and a bottom side 310b separated by the thickness. The foldable luminaire 300 further comprises a plurality of LED light sources (not shown) arranged to emit LED light. The LED light may be directed towards or out from the body. The foldable luminaire 300 also comprises a first flexible material layer 330a attached at the bottom side 310b of the body 310.

Further, two slits 340 are formed in the body 310. The two slits 340 extend from the top side 310a to the bottom side 310b (or the other way around) of the body such that a plurality of body segments 1, 2, 3, 4 are formed in the body 310. One of the two slits 340 corresponds to a rotational axis extending in the first flexible material layer 330 between the plurality of body segments 1, 2, 3, 4.

The rotational axis is associated with one of the two slits 340 and extends along a direction corresponding to the direction of its associated slit. The plurality of body segments 1, 2, 3, 4 are rotatable about the rotational axis for folding the foldable luminaire.

The body 310 extends in a square shape along a first axis A1 and a second axis A2. As another example, that the light shaping body may have a rectangular shape.

Further, the foldable luminaire 300 disclosed in FIG. 3a comprises a second flexible material layer 330b attached at the top side 310a of the body 310. In FIG. 3a, the two slits 340 are formed in the body forming four body segments 1, 2, 3, 4. A first slit 340 is formed along a first middle line along the first axis A1 and a second slit 340 is formed along a second middle line along the second axis A2. The body segments 1, 2, 3, 4 created are therefore similar in size. In other words, the body 310 is divided into four square segments (or square blocks). The first flexible material layer 330a is attached at the bottom side 310b of the body 310 such that it covers a majority the first slit 340 of the two slits 340. However, in this particular embodiment the first flexible layer 330a is divided into two flexible layers 330a attached at the bottom side 310b of the body 310 so that the second slit 340 is not covered. In other embodiments, the first flexible material layer 330a may only partially cover the first slit 340. The second flexible material layer 330b is attached at the top side 310a of the body 310 such that it at least partially covers the second slit 340 of the two slits 340. In FIG. 3a, the second flexible material layer 330b covers approximately half of the second slit 340.

The addition of the second flexible material layer 330b allows the foldable luminaire 300 to be folded in multiple directions as illustrated in FIGS. 3b and 3c. A second rotational axis is formed in the second flexible material layer 330b.

FIGS. 3b and 3c show the foldable luminaire 300 depicted in FIG. 3a while being folded.

The foldable luminaire 300 in FIG. 3a can be folded about a rotational axis formed in the second flexible material layer in order to reach the configuration of FIG. 3b. After this, the second body segment 2 can be folded over the fourth body segment 4 by being folded about a rotational axis formed in the first flexible material layer 330a. Similarly, the first body segment can be folded over the third body segment 3 by being folded about a rotational axis formed in the first flexible material layer 330a. After these folding operations, the configuration (or folded state) depicted in FIG. 3c may be reached.

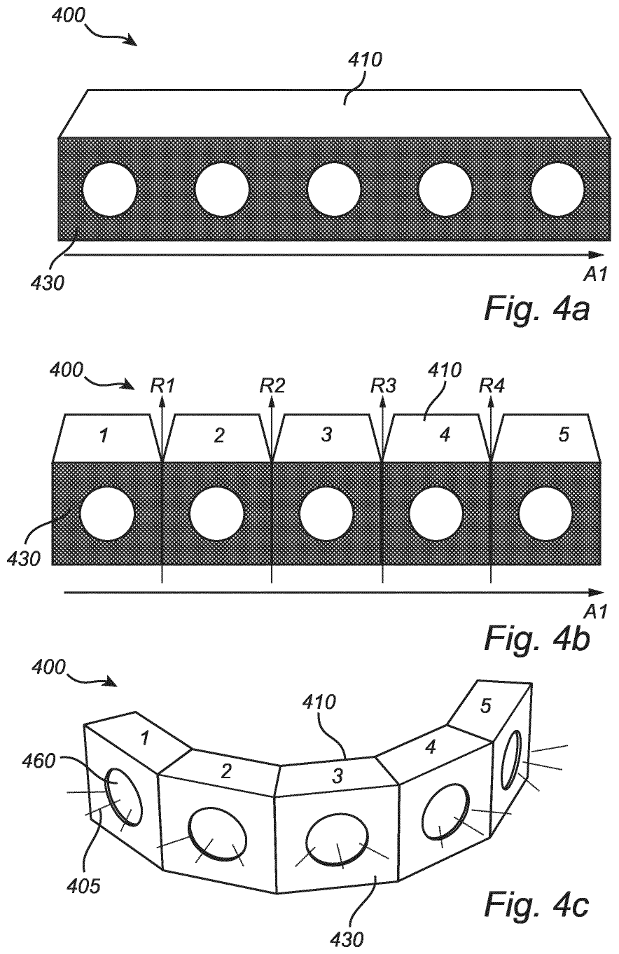

FIGS. 4a, 4b and 4c show a foldable luminaire 400 according to an exemplifying embodiment of the present disclosure.

FIG. 4a shows the luminaire 400 before formation of slits so the luminaire as shown in FIG. 4 is per se not foldable yet.

FIGS. 4a-c show a luminaire that may include the features described in the above embodiments with reference to the preceding figures. For example, the luminaire 400 includes a body 410 and a first flexible material layer 430. The body 410 comprises a number of reflectors 460, in this example five, configured to shape, reflect or redirect the light emitted from the LED light sources (not shown). The reflectors 460 may for example be one of a specular reflecting collimator, a diffuse reflective collimator, a total internal reflection collimator, and a collimator lens. In FIG. 4b, a plurality of slits 440, four in this particular example, has been made in the body 410 forming a plurality of body segments 1, 2, 3, 4, 5.

In FIG. 4c, the foldable luminaire 400 has been shaped into an arc by rotating or bending the body segments 1, 2, 3, 4, 5 about the rotational axes R1, R2, R3, R4 shown in FIG. 4b. However, any shape is conceivable and the foldable luminaire 400 can for example be shaped in the form of a square, a cylinder or the like. Shaping the foldable luminaire 400 affects the light emitted from the foldable luminaire 400, thereby providing the possibility for a more aesthetic appearance.

The reflectors 460 may shape, redirect and reflect the light from the LED light sources, for example a LED strip comprising a plurality of LED light sources such as LEDs, into luminaire light 405. The luminaire light 405 may be used to provide lighting to any environment.

While the present invention has been illustrated in the appended drawings and the foregoing description, such illustration is to be considered illustrative or exemplifying and not restrictive; the present invention is not limited to the disclosed embodiments. Other variations to the disclosed embodiments can be understood and effected by those skilled in the art in practicing the claimed invention, from a study of the drawings, the disclosure, and the appended claims. In the appended claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

The person skilled in the art realizes that the present invention by no means is limited to the preferred embodiments described above. On the contrary, many modifications and variations are possible within the scope of the appended claims. For example, the luminaire body and luminaire segments, etc., may have different shapes, dimensions and/or sizes than those depicted/described.

1. A foldable luminaire comprising:
a body having a thickness and comprising a top side and a bottom side separated by the thickness;
a plurality of LED light sources arranged to, in operation, emit LED light;
a first flexible material layer attached to the bottom side of the body, wherein the first flexible material layer comprises electrical connecting elements for providing power to the plurality of LED light sources; and
a plurality of light shaping elements arranged in the body and configured to at least partially shape or redirect the LED light into luminaire light;
wherein a plurality of slits is arranged in the body, the plurality of slits extending from the top side of the body to the bottom side of the body such that a plurality of body segments with respective lengths are formed in the body, wherein a slit thereby corresponds to at least one rotational axis in the first flexible material layer, wherein each of the plurality of body segments comprises a LED light source of the plurality of LED light sources and a light shaping element of the plurality of light shaping elements;
wherein a rotational axis of the at least one rotational axis extends along a direction corresponding to the direction of its corresponding slit,
wherein at least one of the plurality of body segments is rotatable about the at least one rotational axis for folding of the foldable luminaire, and
wherein a first body segment has a first length along the first axis and wherein a third body segment has a third length along the first axis different from the first length.

2. The foldable luminaire according to claim 1, wherein the body extends along a first axis, and wherein the plurality of slits intersects the first axis so that the body segments are formed extending along at least the first axis, and wherein the first flexible material layer extends, along the first axis, from a first body segment to a last body segment.

3. The foldable luminaire according to claim 1, or wherein the flexible material layer is formed by two layers, one for flexible folding and the other for providing electrical connection to the LEDs.

4. The foldable luminaire according to claim 1, wherein the light shaping element is chosen from at least one of a specular reflecting collimator, a diffuse reflective collimator, a total internal reflection collimator, and a collimator lens.

5. The foldable luminaire according to claim 1, wherein a fourth body segment has a fourth length along the first axis different from the first length and the third length.

6. The foldable luminaire according to claim 1, wherein a first body segment has a first length along the first axis and wherein a second body segment, arranged adjacent to the first body segment along the first axis, has a second length along the first axis equal to the first length.

7. The foldable luminaire according to claim 6, wherein a third body segment, arranged adjacent to the second body segment along the first axis, has a third length along the first axis, wherein the third length is less than the first length and the second length.

8. The foldable luminaire according to claim 6, wherein the respective length along the first axis of at least one of every other body segment, starting from a third body segment arranged directly after the second body segment along the first axis, is equal to the thickness multiplied by an integer Z, wherein Z starts at one and increases by one for every other body segment.

9. The foldable luminaire according to claim 6, wherein the respective length along the first axis of at least one of every other body segment, starting from a fourth body segment arranged directly after the third body segment along the first axis, is equal to the first length plus the thickness multiplied by an integer Y, wherein Y starts at zero and increases by one for every other body segment.

10. The foldable luminaire according to claim 1, wherein the body extends in a square or rectangular shape along a first axis and a second axis.

11. The foldable luminaire according to claim 10, further comprising a second flexible material layer attached at the top side of the body.

12. The foldable luminaire according to claim 10, or wherein the plurality of slits includes two slits formed in the body, and wherein a first slit of the two slits is formed along a first middle line of the square or rectangular shape along the first axis and a second slit of the two slits extends along a second middle line of the square or rectangular shape along the second axis and orthogonal to the first middle line.

13. The foldable luminaire according to claim 12, wherein the first flexible material layer is attached at the bottom side of the body such that it at least partially covers the first slit of the two slits, and wherein the second flexible material layer is attached at the top side of the body such that it at least partially covers the second slit of the two slits.

14. The foldable luminaire according to claim 1, further comprising a LED strip comprising the plurality of LED light sources and optionally the first flexible material layer.
